(19) United States
(12) Patent Application Publication
(10) Pub. No.: US 2026/0323914 A1
(43) Pub. Date: Oct. 15, 2026

(54) SEMICONDUCTOR MEMORY DEVICE

(71) Applicant: Samsung Electronics Co., Ltd., Suwon-si (KR)

(72) Inventors: Jae Kang KOH, Suwon-si (KR); Kyung Hwan LEE, Suwon-si (KR); Sang Min KANG, Suwon-si (KR); Jung Pyo HONG, Suwon-si (KR)

(21) Appl. No.: 19/574,707

(22) Filed: Mar. 23, 2026

(30) Foreign Application Priority Data
Apr. 10, 2025 (KR) 10-2025-0046761

(51) Int. Cl. H10B 12/00

(52) U.S. Cl. CPC H10B 12/30

(57) ABSTRACT

A semiconductor memory device includes a substrate, word lines which are stacked on the substrate, a channel region which is disposed between the word lines, a first contact structure which is connected to one end of the channel region, a second contact structure which is connected to the other end of the channel region, a bit line which is in contact with the first contact structure, and an electrode structure which is in contact with the second contact structure, wherein the first contact structure includes a two-dimensional semiconductor material layer of multilayers which are stacked between the channel region and the bit line, and the second contact structure includes a two-dimensional semiconductor material layer of multilayers which are stacked between the channel region and the electrode structure.

### CROSS-REFERENCE TO RELATED APPLICATION

This application claims priority from Korean Patent Application No. 10-2025-0046761 filed on Apr. 10, 2025 in the Korean Intellectual Property Office, and all the benefits accruing therefrom under 35 U.S.C. 119, the contents of which in their entirety being herein incorporated by reference.

### BACKGROUND

In the case of conventional two-dimensional or planar semiconductor elements, the degree of integration is mainly determined by an area occupied by unit memory cells, and is therefore greatly affected by the level of fine pattern forming technology. However, since ultra-expensive apparatuses are required to miniaturize the pattern, the degree of integration of the two-dimensional semiconductor elements is increasing, but is still limited. Accordingly, three-dimensional semiconductor elements including memory cells arranged three-dimensionally have been proposed.

### SUMMARY

Some aspects of the present disclosure provide semiconductor memory devices having improved performance and reliability.

However, aspects of and improvements provided by the present disclosure are not restricted to the ones set forth above. The above and other aspects of the present disclosure will become more apparent to one of ordinary skill in the art to which the present disclosure pertains by referencing the detailed description of the present disclosure given below.

A semiconductor memory device according to some implementations of the present disclosure includes a substrate, word lines which are stacked on the substrate, a channel region which is disposed between the word lines, a first contact structure which is connected to one end of the channel region, a second contact structure which is connected to the other end of the channel region, a bit line which is in contact with the first contact structure, and an electrode structure which is in contact with the second contact structure, wherein the first contact structure includes a two-dimensional semiconductor material layer of multilayers which are stacked between the channel region and the bit line, and the second contact structure includes a two-dimensional semiconductor material layer of multilayers which are stacked between the channel region and the electrode structure.

A semiconductor memory device according to some implementations of the present disclosure includes a substrate, word lines which are stacked on the substrate in a vertical direction, a channel region which is disposed between the word lines, and includes a two-dimensional semiconductor material layer of a monolayer, an insulating pattern which is disposed between the word lines in the vertical direction, a first contact structure which is connected to a first source/drain region of the channel region, a second contact structure which is connected to a second source/drain region of the channel region, a bit line which extends in the vertical direction, and is connected to the first contact structure, and an electrode structure which is connected to the second contact structure, wherein the first contact structure is disposed between the channel region and the bit line, and includes a two-dimensional semiconductor material layer of at least one layer that surrounds at least a part of the first source/drain region, and the second contact structure is disposed between the channel region and the electrode structure, and includes a two-dimensional semiconductor material layer of at least one layer that surrounds at least a part of the second source/drain region.

A semiconductor memory device according to some implementations of the present disclosure includes a substrate, word lines which extend on the substrate in a first horizontal direction parallel to an upper side of the substrate, and are spaced apart from each other in a second horizontal direction different from the first horizontal direction, a channel region which is disposed between the word lines in the second horizontal direction, and includes a two-dimensional semiconductor material layer of a monolayer, a first contact structure which is connected to a first region of the channel region, a second contact structure which is connected to a second region of the channel region, a bit line which extends in the second horizontal direction on the substrate, and is connected to the first contact structure, and an electrode structure which is connected to the second contact structure, wherein the first contact structure is disposed between the first region and the bit line, and includes two-dimensional semiconductor material layers of multilayers that are in contact with the first region, and the second contact structure is disposed between the second region and the electrode structure, and includes two-dimensional semiconductor material layers of multilayers that are in contact with the second region.

Specific details of other implementations are included in the detailed description and drawings.

### BRIEF DESCRIPTION OF DRAWINGS

The above and other aspects and features of the present disclosure will become more apparent by describing in detail illustrative examples thereof with reference to the attached drawings, in which:

FIG. 1 is layout diagram showing an example of a semiconductor memory device;

FIG. 2 is a plan view illustrating an example of a semiconductor memory device;

FIG. 3 is an example of a cross-sectional view taken along line A-A’ of FIG. 2;

FIG. 4 is an enlarged view of a P region of FIG. 2;

FIG. 5 is a diagram illustrating an example of a semiconductor memory device;

FIG. 6 is a plan view illustrating an example of a semiconductor memory device;

FIG. 7 is an example of a cross-sectional view taken along line B-B’ of FIG. 6;

FIG. 8 is a plan view illustrating an example of a semiconductor memory device;

FIG. 9 is an example of a cross-sectional view taken along line C-C’ of FIG. 8;

FIGS. 10 - 16 are diagrams illustrating an example of a a method of fabricating a semiconductor memory device;

FIGS. 17 - 21 are diagrams illustrating an example of a method of fabricating a semiconductor memory device;

FIGS. 22 - 27 are diagrams illustrating an example of a method of fabricating a semiconductor memory device.

### DETAILED DESCRIPTION

Although terms such as first and second are used to describe various elements or components in the present specification, it will be understood that these elements or components are not limited by these terms, which are used merely as labels. These terms are only used to distinguish a single element or component from other elements or components. Therefore, a first element or component referred to below may equally be referred to as a second element or component within the technical idea of the present disclosure.

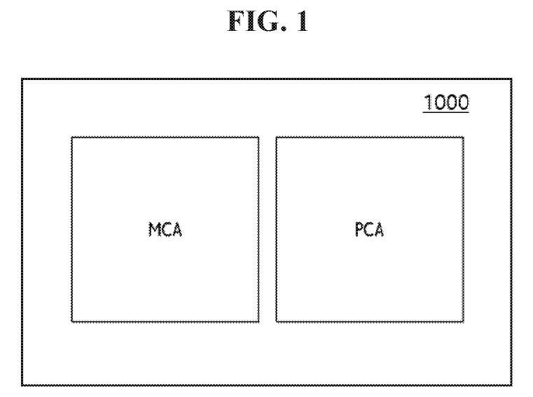

FIG. 1 is layout diagram showing an example of a semiconductor memory device.

Referring to FIG. 1, a semiconductor memory device 1000 may include a cell array region MCA and a peripheral circuit region PCA. In some implementations, the cell array region MCA may be a region in which memory cell transistors of a dynamic random access memory (DRAM) device are disposed, and the peripheral circuit region PCA may be a peripheral circuit region of the DRAM device. For example, the peripheral circuit region PCA may include a peripheral circuit transistor for sending signals and/or power to a memory cell transistor included in the cell array region MCA. In some implementations, the peripheral circuit transistor may be included in various circuits (e.g., circuits of the peripheral circuit region PCA) such as a command decoder, a control logic, an address buffer, a row decoder, a column decoder, a sense amplifier, and a data input/output circuit.

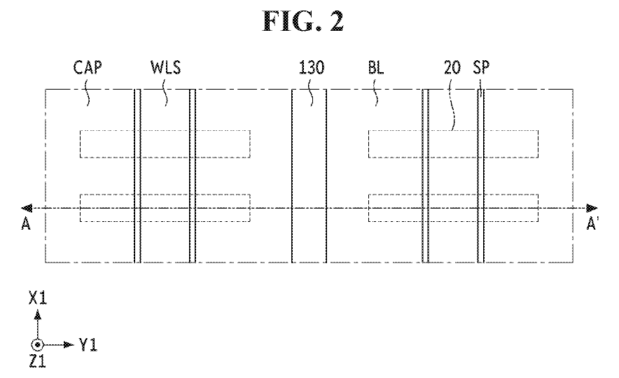

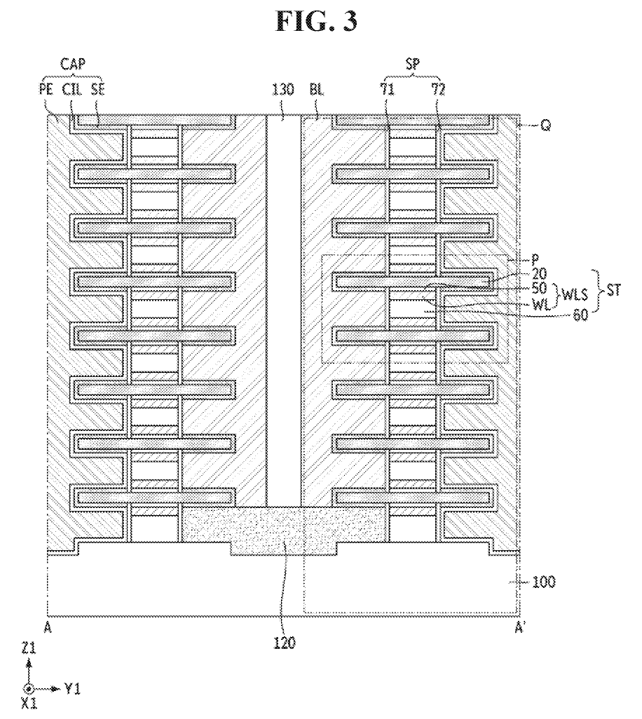

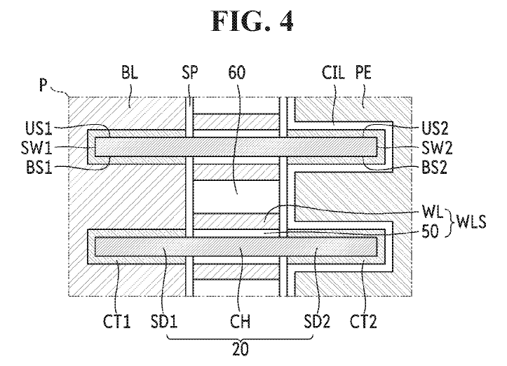

FIG. 2 is a plan view illustrating an example of a semiconductor memory device. FIG. 3 is an example of a cross-sectional view taken along line A-A’ of FIG. 2. FIG. 4 is an enlarged view of a P region of FIG. 2. For reference, FIG. 2 schematically shows an example of a cell array region MCA portion of FIG. 1.

Referring to FIGS. 2 to 4, the semiconductor memory device may include a first substrate 100, a stack structure ST, a word line structure WLS, a bit line BL, an electrode structure CAP, a semiconductor film 20, a first contact structure CT1, a second contact structure CT2, and a spacer pattern SP.

An upper side of the first substrate 100 may be disposed in a plane in which a first direction X1 and a second direction Y1 extend. The upper side of the first substrate 100 may be perpendicular to a third direction Z1. In this specification, the first direction X1, the second direction Y1, and the third direction Z1 may intersect each other. The first direction X1, the second direction Y1, and the third direction Z1 may be substantially perpendicular to each other. In some implementations, the first direction X1 may be referred to as a first horizontal direction, the second direction Y1 may be referred to as a second horizontal direction, and the third direction Z1 may be referred to as a vertical direction.

The first substrate 100 may be bulk silicon or silicon-on-insulator (SOI). The first substrate 100 may be a silicon substrate or may include other materials, for example, but not limited to, silicon germanium, silicon germanium on insulator (SGOI), indium antimonide, lead telluride, indium arsenide, indium phosphide, gallium arsenide or gallium antimonide. In the following description, the first substrate 100 will be described as a substrate including silicon, without being limited thereto.

The stack structure ST may be disposed on the first substrate 100. The stack structure ST may include a plurality of word line structures WLS, a plurality of insulating patterns 60, and a plurality of semiconductor films 20. The plurality of stack structures ST may be stacked alternately and repeatedly in the third direction Z1.

The word line structure WLS may include a word line WL and a gate insulating film 50. For example, the gate insulating film 50 may be disposed between the word line WL and the semiconductor film 20 that are adjacent to each other in the third direction Z1.

The word lines WL may be conductive patterns (e.g., metal conductive lines) stacked on the first substrate 100 in the third direction Z1. Each word line WL may extend in the first direction X1. Each word line WL may be spaced apart in the second direction Y1 from a planar viewpoint. The word lines WL adjacent to each other may be spaced apart in the third direction Z1 from a vertical viewpoint.

The word lines WL may include a conductive material. As an example, the word lines WL may include, but are not limited to, at least one of doped semiconductor materials (doped silicon, doped silicon-germanium, doped germanium, etc.), conductive metal nitrides (titanium nitride, tantalum nitride, etc.), metals (tungsten, titanium, tantalum, etc.), and metal-semiconductor compounds (tungsten silicide, cobalt silicide, titanium silicide, etc.).

The gate insulating film 50 may include at least one of a high dielectric constant insulating film, a silicon oxide film, a silicon nitride film, and a silicon oxynitride film. As an example, the high dielectric constant material may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide or lead zinc niobate.

The insulating patterns 60 may be provided between word lines WL adjacent in the third direction Z1. The insulating patterns 60 may electrically separate the word lines WL. The plurality of insulating patterns 60 and the plurality of word line structures WLS may be alternately and repeatedly stacked in the third direction Z1.

The insulating patterns 60 may include an insulating material. The insulating patterns 60 may include at least one of, for example, a silicon oxide film, a silicon nitride film, a silicon oxynitride film, a carbon-containing silicon oxide film, a carbon-containing silicon nitride film, and a carbon-containing silicon oxynitride film. As an example, the insulating patterns 60 may include a silicon oxide film. The word lines WL, the gate insulating film 50, the insulating pattern 60, and a channel region CH to be described below may overlap each other from a planar viewpoint, e.g., along the vertical direction.

The bit lines BL may be conductive patterns (e.g., a metal conductive line) extending in a vertical direction (i.e., the third direction Z1) from the upper side of the first substrate 100. The bit lines BL may be arranged in the second direction Y1. The bit lines BL adjacent to each other may be spaced apart in the second direction Y1.

A gate of the memory cell transistor may be connected to the word line WL, and a first source/drain region of the memory cell transistor may be connected to the bit line BL. A second source/drain region of the memory cell transistor may be connected to the electrode structure CAP. The second source/drain region of the memory cell transistor may be connected to the storage electrode of the capacitor.

The electrode structure CAP may be connected to the second source/drain region SD2. In some implementations, the electrode structure CAP may be a capacitor. The electrode structure CAP may include a storage electrode SE, a plate electrode PE, and a capacitor dielectric film CIL. The electrode structures CAP may share the capacitor dielectric film CIL and the plate electrode PE. For example, a plurality of storage electrodes SE connected to each of the second source/drain regions SD2 are provided, and one capacitor dielectric film CIL may cover the surface of each storage electrode SE. One plate electrode PE may cover the capacitor dielectric film CIL. Each electrode structure CAP may be defined by the storage electrode SE.

The plate electrode PE may include, for example, but is not limited to, doped semiconductor materials, conductive metal nitrides (e.g., titanium nitride, tantalum nitride, niobium nitride, or tungsten nitride), metal (e.g., ruthenium, iridium, titanium, niobium, tungsten, cobalt, molybdenum or tantalum), and conductive metal oxides (e.g., iridium oxide or niobium oxide), and the like. As an example, the plate electrode PE may include conductive metal nitrides, metals, and conductive metal oxides. The conductive metal nitrides, metals, and conductive metal oxides may be included in the metallic conductive film.

The capacitor dielectric film CIL may include, for example, high dielectric constant materials (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate or combinations thereof). In some implementations, the capacitor dielectric film CIL may include a stacked film structure in which zirconium oxide, aluminum oxide, and zirconium oxide are sequentially stacked. In some implementations, the capacitor dielectric film CIL may include hafnium (Hf).

The semiconductor films 20 may be stacked in the third direction Z1. For example, word lines WL may be provided between the semiconductor films 20 adjacent to each other in the third direction Z1. The word lines WL adjacent to each other in the third direction Z1 may be spaced apart with the gate insulating film 50 and the semiconductor film 20 interposed therebetween. The semiconductor film 20 may also be provided between the gate insulating films 50 adjacent to each other in the third direction Z1.

The semiconductor films 20 may be spaced apart from each other in the first direction X1 and the third direction Z1. The semiconductor films 20 may extend in the second direction Y1. For example, the semiconductor films 20 may be three-dimensionally arranged on the first substrate 100.

The semiconductor films 20 may penetrate, or extend in, the word line WL in the second direction Y2. Each of the word lines WL may have a structure (e.g., a gate-all-around structure) that surrounds the channel region CH of the semiconductor film 20. A gate insulating film 50 may be interposed between the semiconductor film 20 and the word line WL. The gate insulating film 50 may be in contact with the semiconductor film 20. The word line WL may be interposed between the gate insulating film 50 and the insulating pattern 60. The gate insulating film 50 may be in contact with the word line WL but, in some implementations, not in contact with the insulating pattern 60.

The semiconductor film 20 may include a first source/drain region SD1, a channel region CH, and a second source/drain region SD2.

The first source/drain region SD1 may be disposed on one side of the channel region CH. The second source/drain region SD2 may be disposed on the other side of the channel region CH. The first source/drain region SD1 and the second source/drain region SD2 may be symmetrical to each other with the channel region CH interposed between them. Each of the first source/drain region SD1 and the second source/drain region SD2 may include, but is not limited to, a semiconductor material doped with impurities.

The first source/drain region SD1 may be connected to the bit line BL. The second source/drain region SD2 may be connected to the electrode structure CAP. For example, the second source/drain region SD2 may be connected to the storage electrode SE of the electrode structure CAP. In some implementations, the second contact structure CT2 may be provided as the storage electrode SE, but the technical idea of the present disclosure is not limited thereto. The second contact structure CT2 may be in contact with the capacitor dielectric film CIL.

The first source/drain region SD1 may include a first upper side US1 that extends in the second direction Y1 toward the bit line BL, a first lower side BS1 that faces the first upper side, and a first side wall SW1 that connects the first upper side US1 and the first lower side BS1.

The second source/drain region SD2 may include a second upper side US2 that extends in the second direction Y1 toward the plate electrode PE, a second lower side BS2 that faces the second upper side US2, and a second side wall SW2 that connects the second upper side US2 and the second lower side BS2.

The first contact structure CT1 may be in contact with each of the first upper side US1, the first side wall SW1, and the first lower side BS1. The first contact structure CT1 may surround each of the first upper side US1, the first side wall SW1, and the first lower side BS1. The second contact structure CT2 may be in contact with each of the second upper side US2, the second side wall SW2, and the second lower side BS2. The second contact structure CT2 may surround each of the second upper side US2, the second side wall SW2, and the second lower side BS2.

The first contact structure CT1 may include a two-dimensional semiconductor material layer of at least one layer stacked between the channel region CH and the bit line BL. The first contact structure CT1 may be in contact with one end of the channel region CH. In some implementations, one end of the channel region CH may also be referred to as a first source/drain region SD1.

The second contact structure CT2 may include a two-dimensional semiconductor material layer of at least one layer that is stacked between the channel region CH and the electrode structure CAP. The second contact structure CT2 may be in contact with the other end of the channel region CH. In some implementations, the other end of the channel region CH may also be referred to as a second source/drain region SD2.

The semiconductor film 20 may include a two-dimensional material having a two-dimensional crystal structure. The two-dimensional material may have a layered structure of monolayer or multilayer. Each layer constituting the two-dimensional material may have a thickness of an atomic level. For example, the semiconductor film 20 may include graphene, TMD (Transition Metal Dichalcogenide), black phosphorus, or hBN (hexagonal Boron-Nitride).

The TMD may include, for example, one transition metal among Mo, W, Nb, V, Ta, Ti, Zr, Hf, Tc, and Re, and one chalcogen element among S, Se, and Te. The TMD may be represented, for example, as MX₂, here, M represents a transition metal and X represents a chalcogen element. For example, M may be Mo, W, Nb, V, Ta, Ti, Zr, Hf, Tc, Re, or the like, and X may be S, Se, Te, or the like. Thus, for example, the TMD may include MoS₂, MoSe₂, MoTe₂, WS₂, WSe₂, WTe₂, ZrS₂, ZrSe₂, HfS₂, HfSe₂, NbSe₂, ReSe₂, etc. Alternatively, the TMD may not be expressed as MX₂. In this case, for example, the TMD may include CuS, which is a compound of Cu which is a transition metal, and S which is a chalcogen element. On the other hand, the TMD may be a chalcogenide material including a non-transition metal. The non-transition metal may include, for example, Ga, In, Sn, Ge, Pb, etc. In this case, the TMD may include a compound such as Ga, In, Sn, Ge, and Pb, and a chalcogen element such as S, Se, and Te. For example, the TMD may include SnSe₂, GaS, GaSe, GaTe, GeSe, In₂Se₃, InSnS₂, etc.

The channel region CH may include a two-dimensional semiconductor material layer of a monolayer (a two-dimensional semiconductor material monolayer). In this case, the two-dimensional semiconductor material layer included in the channel region CH may be made of a single material. However, the channel region CH may include two-dimensional semiconductor material layers including different materials from each other, without being limited thereto.

The first contact structure CT1 may include a two-dimensional semiconductor material layer of at least one layer. The first contact structure CT1 may include two-dimensional semiconductor material layers of, or forming, a multilayer structure. The number of layers of the two-dimensional semiconductor material layer included in the first contact structure CT1 may be, but is not limited to, 2 or more and 10 or less. For example, the first contact structure CT1 may include at least one of MoS₂, MoSe₂, WS₂, and WSe₂.

The second contact structure CT2 may include a two-dimensional semiconductor material layer of at least one layer. The second contact structure CT2 may include two-dimensional semiconductor material layers of a multilayer structure. The number of layers of the two-dimensional material layer included in the second contact structure CT2 may be, but is not limited to, 2 or more and 10 or less. For example, the second contact structure CT2 may include at least one of MoS₂, MoSe₂, WS₂, and WSe₂.

For example, the two-dimensional semiconductor material layer of the first contact structure CT1 and the two-dimensional semiconductor material layer of the second contact structure CT2 may include the same material as each other. As another example, the two-dimensional semiconductor material layer of the first contact structure CT1 and the two-dimensional semiconductor material layer of the second contact structure CT2 may include different materials from each other.

For example, the first contact structure CT1 may include two-dimensional semiconductor material layers including different materials from each other. The second contact structure CT2 may include two-dimensional semiconductor material layers including different materials from each other.

As another example, the first contact structure CT1 may include two-dimensional semiconductor material layers of a multilayer structure including the same material as each other. The second contact structure CT2 may include two-dimensional semiconductor material layers of a multilayer structure including the same material as each other.

The spacer pattern SP may be provided between the bit line BL and the word lines WL, and between the electrode structure CAP and the word lines WL, respectively. The spacer pattern SP may include a first spacer pattern 71 and a second spacer pattern 72. The gate insulating film 50, the word lines WL, and the insulating pattern 60 may be disposed between the first spacer pattern 71 and the second spacer pattern 72.

The first spacer pattern 71 may extend in the first direction X1. The first spacer pattern 71 may be disposed between the bit line BL and the word lines WL in the second direction Y1. The first spacer pattern 71 may electrically separate the bit line BL and the word line WL. The first spacer pattern 71 may be in contact with a partial region of the semiconductor film 20. The first spacer pattern 71 may be in direct contact with the gate insulating film 50, the word lines WL, and the insulating pattern 60. The first spacer pattern 71 may be disposed on one side wall of the gate insulating film 50, one side wall of each of the word lines WL, and one side wall of the insulating pattern 60. The first spacer pattern 71 may be in direct contact with the first source/drain region SD1, but its arrangement is not limited thereto.

The second spacer pattern 72 may be provided between the electrode structure CAP and the word lines WL. The second spacer pattern 72 may extend in the first direction X1. The second spacer pattern 72 may be spaced apart from the first spacer pattern 71 in the second direction Y1. The second spacer pattern 72 may electrically separate the electrode structure CAP from the word lines WL. The second spacer pattern 72 may be in contact with a partial region of the semiconductor film 20. The second spacer pattern 72 may be in direct contact with the gate insulating film 50, the word lines WL, and the insulating pattern 60. The second spacer pattern 72 may be disposed on the other side wall of the gate insulating film 50, the other side wall of each word line WL, and the other side wall of the insulating pattern 60. The second spacer pattern 72 may be in direct contact with the second source/drain region SD2, but its arrangement is not limited thereto.

The spacer pattern SP may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the spacer pattern SP may be formed of a silicon nitride film.

The semiconductor memory device may further include a lower protective pattern 120 and a vertical insulating pattern 130.

The lower protective pattern 120 may be disposed on the first substrate 100. The lower protective pattern 120 may be disposed between the first substrate 100 and the bit line BL. The lower protective pattern 120 may be provided between the word lines WL closest to the first substrate 100. The lower protective pattern 120 may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the lower protective pattern 120 may be formed of a silicon nitride film.

The vertical insulating pattern 130 may be disposed on the lower protective pattern 120. The vertical insulating pattern 130 may be provided between the bit lines BL. The vertical insulating pattern 130 may extend in the third direction Z1 on the lower protective pattern 120. The vertical insulating pattern 130 may cover the side walls of the bit lines BL. The vertical insulating pattern 130 may be formed of at least one insulating material among silicon oxide and silicon oxide.

The semiconductor memory device may further include an upper insulating formed on the stack structure ST. For example, the upper insulating film may be disposed on the semiconductor film 20 disposed on the top of the stack structure ST but is not limited thereto. Although the semiconductor memory device is shown as having eight semiconductor films 20 stacked in the third direction Z1, the number of such films is not limited thereto. For example, the number of stacked semiconductor films 20 may be more than eight.

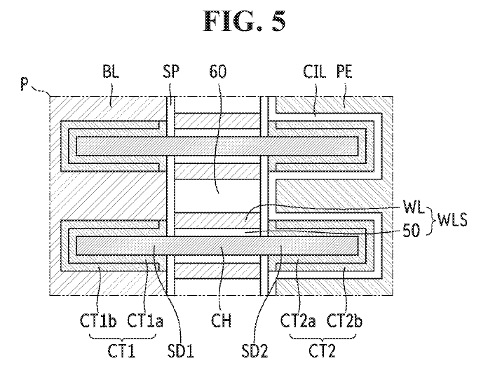

FIG. 5 is a diagram illustrating another example of a semiconductor memory device, e.g., another example corresponding to the view of FIG. 4. For convenience of explanation, repeated parts of contents explained using FIGS. 1 - 4 will be briefly explained or omitted, and the description of FIGS. 1 - 4 can equally or similarly be applied to corresponding elements of FIG. 5 except where noted otherwise or suggested otherwise by context.

Referring to FIG. 5, the first contact structure CT1 of the semiconductor memory device may include a first contact film CT1a that is in contact with the first source/drain region SD1, and a second contact film CT1b that is in contact with the bit line BL on the first contact film CT1a. The second contact structure CT2 includes a third contact film CT2a that is in contact with the second source/drain region SD2, and a fourth contact film CT2b on the third contact film CT2a that is in contact with the electrode structure CAP.

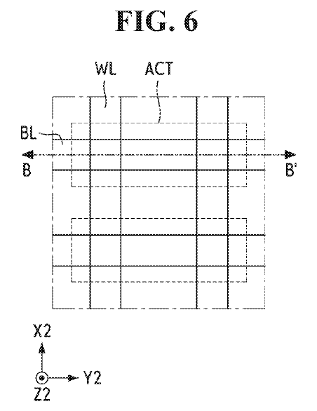

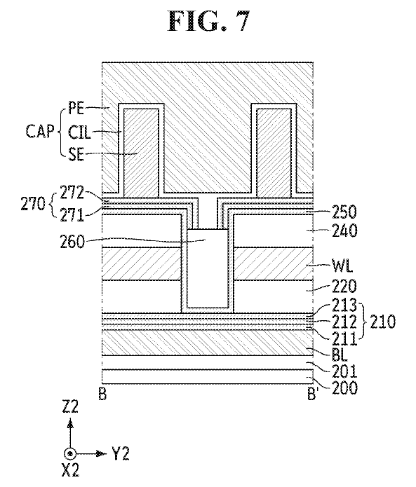

FIG. 6 is a plan view illustrating an example of a semiconductor memory device. FIG. 7 is an example of a cross-sectional view taken along line B-B’ of FIG. 6. For convenience of explanation, repeated parts of contents explained using FIGS. 1 - 5 will be briefly explained or omitted.

Referring to FIGS. 6 and 7, the semiconductor memory device may include a second substrate 200, a bit line BL, a word line WL, an active region ACT, a first contact structure 210, an insulating pillar 260, and a second contact structure 270.

The second substrate 200 may be a silicon substrate or may include other materials, for example, but not limited to, silicon germanium, indium antimonide, lead telluride, indium arsenide, indium phosphide, gallium arsenide or gallium antimonide.

A lower insulating layer 201 and a bit line BL may be sequentially stacked on the second substrate 200. The lower insulating layer 201 may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the lower insulating layer 201 may include a silicon oxide film.

The bit line BL may be disposed on the lower insulating layer 201. The bit lines BL may be conductive patterns (e.g., metal conductive lines) that extend in the second direction Y2 on the second substrate 200. Each bit line BL may be spaced apart in the first direction X2 from a planar viewpoint.

The word lines WL may be conductive patterns (e.g., metal conductive lines) that are stacked on the second substrate 200 in the third direction Z2. Each word line WL may extend in the first direction X2. Each word line WL may be spaced apart in the second direction Y2 from a planar viewpoint. The word lines WL adjacent to each other in the second direction Y2 may be disposed at equal positions in the third direction Z2.

The active regions ACT may be disposed between the word lines WL in the second direction Y2. The active region ACT may correspond to the channel region 250 of FIG. 7. The channel region 250 is disposed between the word lines WL in the second direction Y2 and may include a two-dimensional semiconductor material layer of a monolayer. In some implementations, a gate insulating film may be interposed between the word line WL and the channel region 250.

The first contact structure 210 may be connected to a first region of the channel region 250. The first contact structure 210 may be in contact with the first region of the channel region 250. The bit line BL may be connected to the first contact structure 210. The bit line BL may be in contact with the first contact structure 210. The first contact structure 210 is disposed between the first region and the bit line BL and may include two-dimensional semiconductor material layer of at least one layer that in contact with the first region. The first contact structure 210 may include two-dimensional semiconductor material layers of a multilayer structure each extending in the second direction Y2 on the bit line BL.

The first contact structure 210 may include a first contact film 211, a second contact film 212, and a third contact film 213 that are sequentially stacked on the bit line BL. Each of the first contact film 211, the second contact film 212, and the third contact film 213 may include the above-mentioned two-dimensional semiconductor material layer. Although the number of layers of the contact film included in the first contact structure 210 is shown to be three, the number thereof is not limited thereto. The number of layers of the contact film included in the first contact structure 210 may be at least one layer or more. Each of the first contact film 211, the second contact film 212, and the third contact film 213 included in the first contact structure 210 may include the same two-dimensional semiconductor material or may include different two-dimensional semiconductor materials from each other.

A first mold insulating film 220 and a third mold insulating film 240 may be alternately stacked with the word lines WL in the third direction Z2. The word line WL may be disposed between the first mold insulating film 220 and the third mold insulating film 240. The first mold insulating film 220 may be disposed between the first contact structure 210 and the word line WL in the third direction Z2. The third mold insulating film 240 may be disposed between the word line WL and the second contact structure 270 in the third direction Z2. For example, the first mold insulating film 220 may include a nitride-based material, and the third mold insulating film 240 may include a nitride-based material.

An insulating pillar 260 may be disposed between the word lines WL in the second direction Y2. The insulating pillar 260 may be disposed between the first mold insulating films 220 in the second direction Y2. The insulating pillar 260 may be disposed between at least some parts of the third mold insulating film 240 in the second direction Y2. The insulating pillars 260 may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the insulating pillars 260 may include a silicon oxide film.

The channel region 250 may extend on the upper side of the first contact structure 210 along the upper side and a part of the side wall of the third mold insulating film 240 and the side wall of the insulating pillar 260.

The second contact structure 270 may be connected to the second region of the channel region 250. The second contact structure 270 may be in contact with the second region of the channel region 250. The electrode structure CAP may be connected to the second contact structure 270. The storage electrode SE of the electrode structure CAP may be in contact with the second contact structure 270. The second contact structure 270 may be disposed between the second region and the electrode structure CAP and may include a two-dimensional semiconductor material layer of at least one layer that is in contact with the second region. The second contact structure 270 may include two-dimensional semiconductor material layers of a multilayer structure extending along the upper side and side wall of the third mold insulating film 240, on the second region.

The second contact structure 270 may extend along the upper side of the third mold insulating film 240 and the side wall of the third mold insulating film 240, on the surface of the second region of the channel region 250. The second contact structure 270 may include a fourth contact film 271 and a fifth contact film 272 that are sequentially stacked on the upper side and a part of side face of the channel region 250, and the upper side of the insulating pillar 260. Each of the fourth contact film 271 and the fifth contact film 272 may include the above-mentioned two-dimensional semiconductor material layer. Although the number of layers of the contact film included in the second contact structure 270 is shown to be two, the number thereof is not limited thereto. The number of layers of the contact film included in the second contact structure 270 may be at least one layer or more. Each of the fourth contact film 271 and the fifth contact film 272 included in the second contact structure 270 may include the same two-dimensional semiconductor material or may include different two-dimensional semiconductor materials from each other. The second contact structure 270 may include a different two-dimensional semiconductor material from the first contact structure 210 and may include the same two-dimensional semiconductor material.

The storage electrode SE and the plate electrode PE may include, for example, but are not limited to, doped semiconductor materials, conductive metal nitrides (e.g., titanium nitride, tantalum nitride, niobium nitride, tungsten nitride or the like), metals (e.g., ruthenium, iridium, titanium, niobium, tungsten, cobalt, molybdenum, tantalum or the like), and conductive metal oxides (e.g., iridium oxide, niobium oxide or the like). As an example, the plate electrode PE may include conductive metal nitrides, metals, and conductive metal oxides. The conductive metal nitrides, metals, and conductive metal oxides may be included in the metallic conductive film.

A capacitor dielectric film CIL may include, for example, a high dielectric constant materials (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate or combinations thereof). In some implementations, the capacitor dielectric film CIL may include a stacked film structure in which zirconium oxide, aluminum oxide, and zirconium oxide are sequentially stacked. In some implementations, the capacitor dielectric film CIL may include hafnium (Hf).

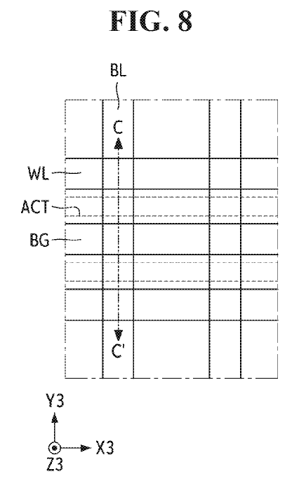

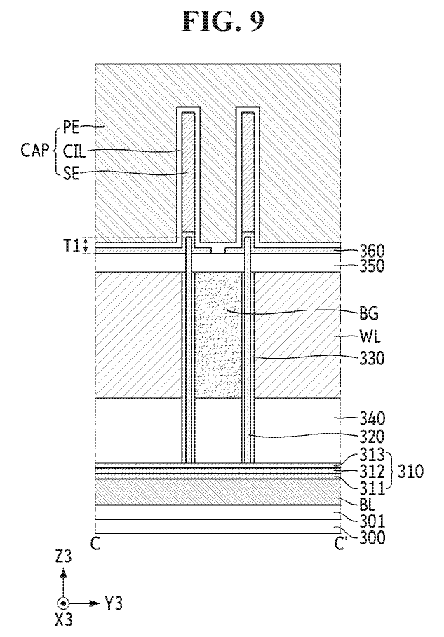

FIG. 8 is a plan view illustrating an example of a semiconductor memory device. FIG. 9 is an example of a cross-sectional view taken along line C-C’ of FIG. 8. For convenience of explanation, repeated parts of contents explained using FIGS. 1 - 7 will be briefly explained or omitted.

Referring to FIGS. 8 and 9, the semiconductor memory device may include a third substrate 300, a bit line BL, a word line WL, a back gate BG, an active region ACT, a first contact structure 310, a first mold insulating film 340, a second mold insulating film 350, and a second mold insulating film 350.

The third substrate 300 may be a silicon substrate, or may include other materials, for example, but not limited to, silicon germanium, indium antimonide, lead telluride, indium arsenide, indium phosphide, gallium arsenide or gallium antimonide.

A lower insulating layer 301 and a bit line BL may be sequentially stacked on the third substrate 300. The lower insulating layer 301 may include at least one of, for example, a silicon oxide film, a silicon nitride film, a silicon oxynitride film, a carbon-containing silicon oxide film, a carbon-containing silicon nitride film, and a carbon-containing silicon oxynitride film. As an example, the lower insulating layer 301 may include the silicon oxide film.

The bit lines BL may be disposed on the lower insulating layer 301. The bit lines BL may be conductive patterns (e.g., metal conductive lines) extending in the second direction Y3 on the third substrate 300. Each bit line BL may be spaced apart in the first direction X3 from a planar viewpoint.

The word lines WL may be conductive patterns (e.g., metal conductive lines) stacked in a third direction Z3 on the third substrate 300. Each word line WL may extend in the first direction X3. Each word line WL may be spaced apart in the second direction Y3 from a planar viewpoint. The word lines WL adjacent to each other in the second direction Y3 may be disposed at equal positions in the third direction Z3.

The back gate BG may be disposed between the word lines WL in the second direction Y3. The back gate BG includes a conductive material, and may include, for example, at least one of a conductive semiconductor material, a conductive metal nitride, a conductive metal silicon nitride, a metal carbonitride, a conductive metal silicide, a two-dimensional material, and a metal.

The active region ACT may be disposed between the word lines WL in the second direction Y3. The active region ACT may correspond to the channel region 320 of FIG. 9. The channel region 320 is disposed between the word lines WL in the second direction Y3 and may include a two-dimensional semiconductor material layer of a monolayer. The channel region 320 may protrude from the upper side of the second mold insulating film 350 to be described below by a first length T1 in the third direction Z3.

The gate insulating film 330 may be interposed between the word line WL and the channel region 320. The gate insulating film 330 may be disposed on each side wall of the channel region 320.

The first contact structure 310 may be connected to the first region of the channel region 320. The first contact structure 310 may be in contact with the first region of the channel region 320. The bit line BL may be connected to the first contact structure 310. The bit line BL may be in contact with the first contact structure 310. The first contact structure 310 is disposed between the first region and the bit line BL and may include two-dimensional semiconductor material layer of at least one layer that is in contact with the first region. The first contact structure 310 may include two-dimensional semiconductor material layers of a multilayer structure each extending in the second direction Y3 on the bit line BL.

The first contact structure 310 may include a first contact film 311, a second contact film 312, and a third contact film 313 that are sequentially stacked on the bit line BL. Each of the first contact film 311, the second contact film 312, and the third contact film 313 may include the above-mentioned two-dimensional semiconductor material layer. Although the number of layers of the contact film included in the first contact structure 310 is shown to be three, the number thereof is not limited thereto. The number of layers of the contact film included in the first contact structure 310 may be at least one layer or more. Each of the first contact film 311, the second contact film 312, and the third contact film 313 included in the first contact structure 310 may include the same two-dimensional semiconductor material or may include different two-dimensional semiconductor materials from each other.

The first mold insulating film 340 may be disposed on the first contact structure 310. For example, the first mold insulating film 340 may include a nitride-based material.

The second mold insulating film 350 may be disposed on the word lines WL and the back gate BG. For example, the second mold insulating film 350 may include a nitride-based material. The second mold insulating film 350 may be in contact with an upper part of the channel region 320.

The second contact structure 360 may be connected to the second region of the channel region 320. The second contact structure 360 may be in contact with the second region of the channel region 320. The electrode structure CAP may be connected to the second contact structure 360. The storage electrode SE of the electrode structure CAP may be in contact with the second contact structure 360. The second contact structure 360 may be disposed between the second region and the electrode structure CAP and may include two-dimensional semiconductor material layer(s) of at least one layer that is in contact with the second region. The second contact structure 360 may include two-dimensional semiconductor material layer(s) of at least one layer extending along the upper side of the second mold insulating film 350, on the second region.

The second contact structure 360 may cover the upper part of the exposed channel region 320, on the second mold insulating film 350. The second contact structure 360 may include two-dimensional semiconductor material layers of a multilayer structure extending along the surface of the channel region 320. Although the number of layers of the contact film included in the second contact structure 360 is shown to be one, the number thereof is not limited thereto. The number of layers of the contact film included in the second contact structure 360 may be at least one layer or more. When the contact films included in the second contact structure 360 form a multilayer structure, each of the contact films may include the same two-dimensional semiconductor material or may include different two-dimensional semiconductor materials from each other.

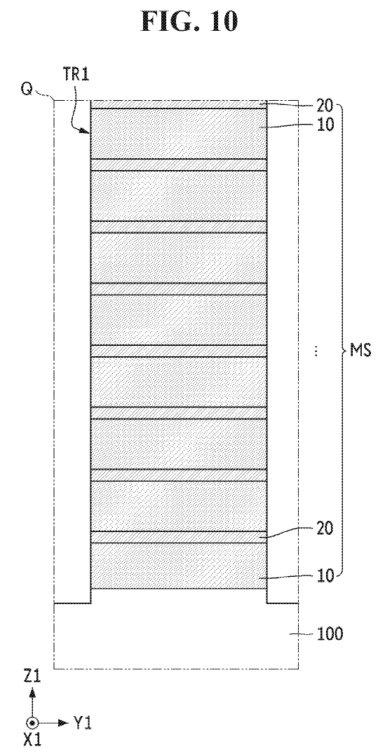

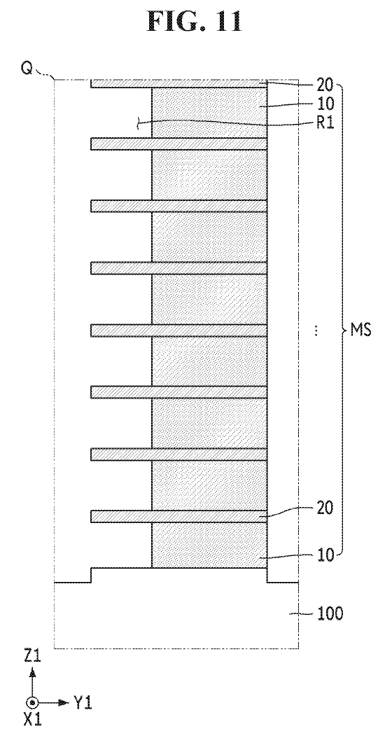

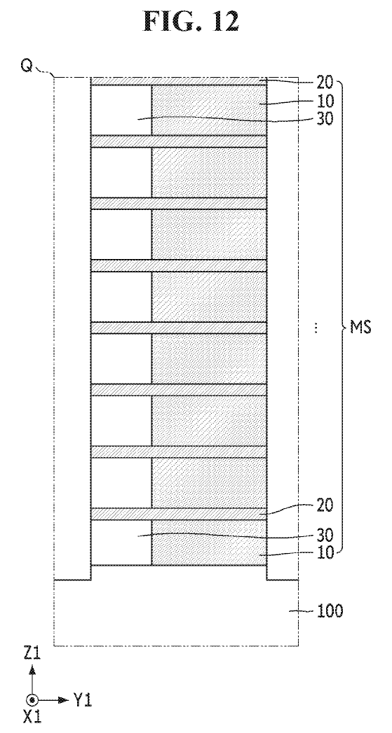

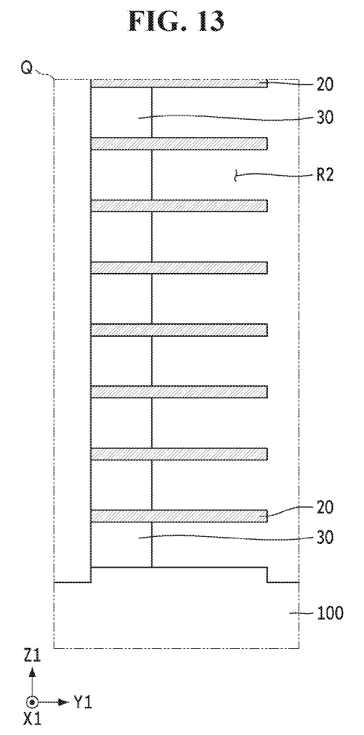

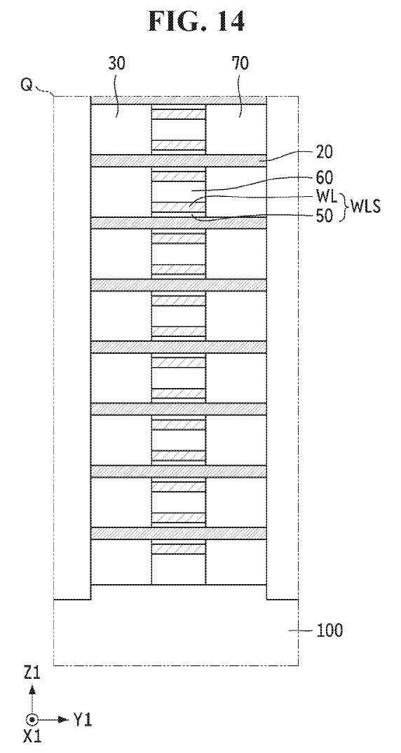

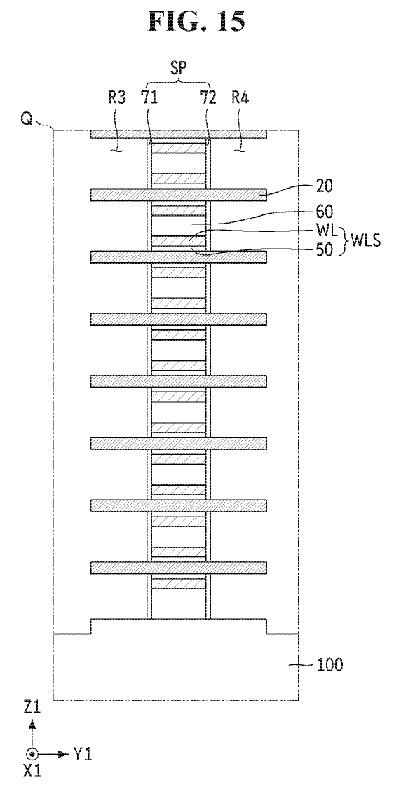

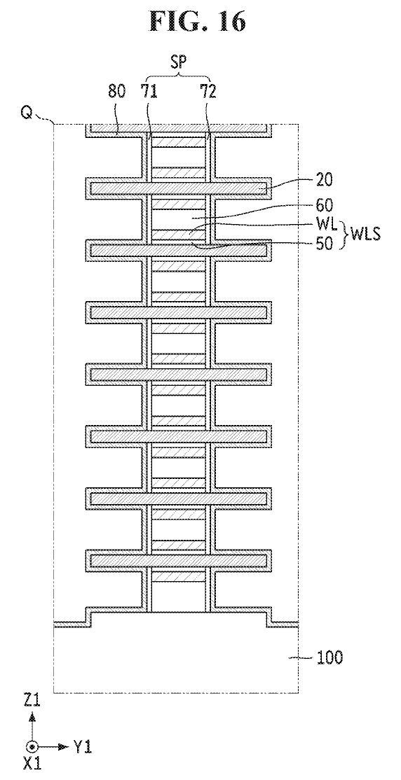

FIGS. 10 - 16 are diagrams illustrating an example of a method of fabricating a semiconductor memory device, e.g., a device as described with respect to FIGS. 1 - 5. For convenience of explanation, repeated parts of contents explained using FIGS. 1 - 5 will be briefly explained or omitted. For reference, FIGS. 10 - 16 are diagrams of a region Q of FIG. 3.

First, referring to FIG. 10, the first substrate 100 may be provided. A mold structure MS may be formed on the first substrate 100.

The mold structure MS may include sacrificial films 10 and semiconductor films 20 that are alternately stacked. For example, the sacrificial films 10 may be formed between the semiconductor films 20 adjacent to each other in the third direction Z1, and the semiconductor films 20 may be formed between the sacrificial films 10 adjacent to each other in the third direction Z1. The thicknesses of the sacrificial films 10 and the semiconductor films 20 are not limited to those shown in the drawings.

The sacrificial films 10 may be formed of a material having an etching selectivity with respect to the semiconductor films 20. For example, the sacrificial film 10 may be formed of at least one of silicon germanium, silicon oxide, silicon nitride, and silicon oxynitride. The semiconductor film 20 may be formed of the two-dimensional material described above.

After that, a first trench TR1 that penetrates the mold structure MS may be formed. The first trench TR1 may expose the side walls of the sacrificial films 10 and the semiconductor films 20. Although not specifically shown, formation of the first trench TR1 may include formation of a mask pattern having openings corresponding to the first trench TR1 on the mold structure MS and etching of the mold structure MS by the use of the mask pattern as an etching mask. The first trench TR1 may expose the upper side of the first substrate 100, and the upper side of the first substrate 100 below the first trench TR1 may be recessed by over-etch during etching to form a recessed region.

Referring to FIG. 11, a part of the sacrificial films 10 exposed by the first trench TR1 may be removed. A part of the sacrificial films 10 may be removed in the horizontal direction to form a first recess R1 on the semiconductor film 20. The first recess R1 may expose a part of the upper side and a part of the lower side of the semiconductor films 20 adjacent to each other in the third direction Z1, and the side wall of the sacrificial film 10 that remains after removal. Formation of the first recess R1 may include a process of etching the sacrificial films 10 by performing an etching process having an etching selectivity to the first substrate 100 and the semiconductor film 20.

Referring to FIG. 12, a first interlayer insulating film 30 may be formed inside the first recess R1. The first interlayer insulating film 30 may be formed on a part of the upper side and a part of the lower side of the semiconductor films 20 exposed by the first recess R1 and on the side wall of the sacrificial film 10. The first interlayer insulating film 30 may be formed between the semiconductor films 20 adjacent to each other in the third direction Z1. Each of the interlayer insulating films 30 may be formed at a height equal to that of each of the sacrificial films 10 in the third direction Z1. The first interlayer insulating film 30 may include an insulating material. The first interlayer insulating film 30 may include at least one of, for example, a silicon oxide film, a silicon nitride film, a silicon oxynitride film, a carbon-containing silicon oxide film, a carbon-containing silicon nitride film, and a carbon-containing silicon oxynitride film. As an example, the first interlayer insulating film 30 may include a silicon oxide film.

Referring to FIG. 13, the remaining sacrificial films 10 may be removed. Each of the sacrificial films 10 may be removed in the horizontal direction to form a second recess R2 on the semiconductor film 20. The second recess R2 may expose other parts of the upper and lower sides of the semiconductor films 20 adjacent to each other in the third direction Z1 and one side wall of the first interlayer insulating film 30. Formation of the second recess R2 may include a process of etching the sacrificial films 10 by performing an etching process having an etching selectivity to the first substrate 100, the semiconductor films 20, and the interlayer insulating films 30.

Referring to FIG. 14, gate insulating films 50 may be formed in the second recess R2, a word line WL may be formed between the gate insulating films 50, and a word line structure WLS may be formed. The word line structure WLS may be formed between the semiconductor films 20 adjacent to each other in the third direction Z1. After that, an etching process in the horizontal direction may be performed on the word line structure WLS. The space formed after the etching process may be filled with an insulating material. As a result, an insulating pattern 60 may be formed between the word line structures WLS adjacent to each other in the third direction Z1, and a second interlayer insulating film 70 may be formed on the side wall of the word line structure WLS. The insulating pattern 60 and the second interlayer insulating film 70 may include at least one of, for example, a silicon oxide film, a silicon nitride film, a silicon oxynitride film, a carbon-containing silicon oxide film, a carbon-containing silicon nitride film, and a carbon-containing silicon oxynitride film. As an example, the insulating pattern 60 and the second interlayer insulating film 70 may include a silicon oxide film.

Referring to FIG. 15, a spacer pattern SP may be formed by removing a part of the first interlayer insulating film 30 and the second interlayer insulating film 70. Each of a third recess R3 and a fourth recess R4 may be formed in a space in which a part of the first interlayer insulating film 30 and a part of the second interlayer insulating film 70 are removed. Only a part of the first interlayer insulating film 30 and the second interlayer insulating film 70 may be removed to form each of a first spacer pattern 71 and a second spacer pattern 72. The third recess R3 exposes a part of the upper side and the lower side of the semiconductor films 20 adjacent to each other in the third direction Z1, and a side wall of the first spacer pattern 71. The fourth recess R4 may expose other parts of the upper and lower sides of the semiconductor films 20 adjacent to each other in the third direction Z1, and the side walls of the second spacer pattern 72. The spacer patterns SP may be formed on each of the upper and lower parts of the semiconductor film 20. The first spacer pattern 71 and the second spacer pattern 72 may be formed on the side walls of the word line structure WLS and the insulating pattern 60.

Referring to FIG. 16, a two-dimensional semiconductor material layer 80 may be formed on one end of the semiconductor film 20, the other end of the semiconductor film 20, and the side walls of the spacer pattern SP. The two-dimensional semiconductor material layer 80 may be formed to surround each of an upper side of one end of the semiconductor film 20, a side wall of one end of the semiconductor film 20, and a lower side of one end of the semiconductor film 20. The two-dimensional semiconductor material layer 80 may be formed to surround each of an upper side of the other end of the semiconductor film 20, a side wall of the other end of the semiconductor film 20, and a lower side of the other end of the semiconductor film 20.

The two-dimensional semiconductor material layer 80 may include the two-dimensional semiconductor material described above. The two-dimensional semiconductor material layer 80 may be formed, for example, but is not limited to, by an atomic layer deposition process (ALD). Multiple two-dimensional semiconductor material layers 80 may be included to form a multilayer structure.

Next, referring to FIG. 3, at least a part of the two-dimensional semiconductor material layer 80 on the spacer pattern SP may be removed. The two-dimensional semiconductor material layer 80 may be formed to surround only one end of the semiconductor film 20 and the other end of the semiconductor film 20.

After that, a bit line BL may be formed at one end of the semiconductor film 20. The bit line BL may be in direct contact with the two-dimensional semiconductor material layer 80. The bit line BL may be in direct contact with the first spacer pattern 71. An electrode structure CAP may be formed at the other end of the semiconductor film 20. The capacitor dielectric film CIL may be formed conformally along the other end of the semiconductor film 20 and the second spacer pattern 72. The two-dimensional semiconductor material layer 80 may be in contact with the capacitor dielectric film CIL of the electrode structure CAP. For example, the two-dimensional semiconductor material layer 80 at the other end of the semiconductor film 20 may be used as a storage electrode SE of the electrode structure CAP, but the configuration is not limited thereto.

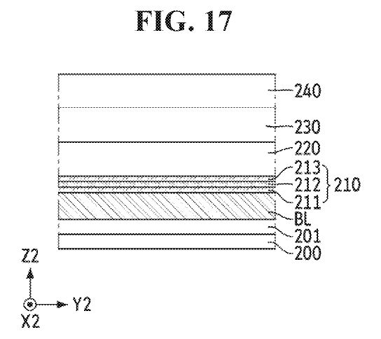

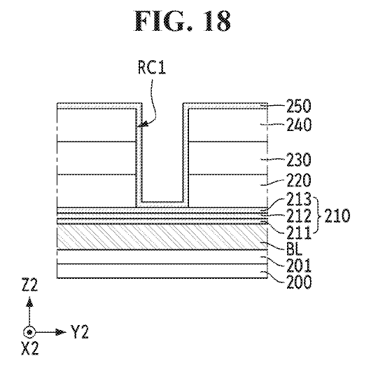

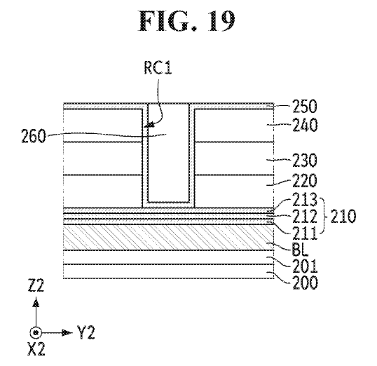

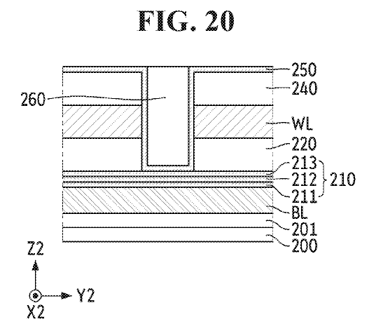

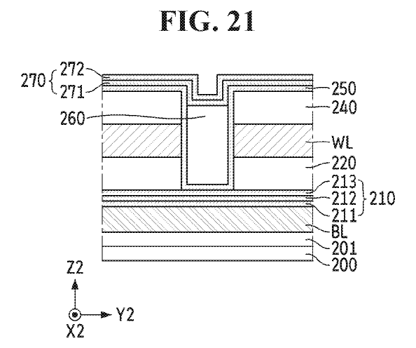

FIGS. 17 - 21 are diagrams illustrating a method of fabricating an example of a semiconductor memory device, e.g., the semiconductor memory device described with respect to FIGS. 6 and 7. For convenience of explanation, repeated parts of contents explained above using FIGS. 6 - 7 will be briefly explained or omitted. For reference, FIGS. 17- 21 are diagrams showing the view of FIG. 7.

Referring to FIG. 17, the lower insulating layer 201 and the bit line BL may be sequentially formed on the second substrate 200.

The first contact structure 210 may be formed on the bit line BL. The first contact structure 210 may include a first contact film 211, a second contact film 212, and a third contact film 213 that are sequentially stacked on the bit line BL. Each of the first contact film 211, the second contact film 212, and the third contact film 213 may include the above-mentioned two-dimensional semiconductor material layer. Although the number of layers of the contact film included in the first contact structure 210 is shown to be three, the number thereof is not limited thereto. The number of layers of the contact film included in the first contact structure 210 may be at least one layer or more. Each of the first contact film 211, the second contact film 212, and the third contact film 213 included in the first contact structure 210 may include the same two-dimensional semiconductor material or may include different two-dimensional semiconductor materials from each other. In some implementations, the first contact structure 210 may be referred to as a first contact structure.

A first mold insulating film 220, a second mold insulating film 230, and a third mold insulating film 240 may be formed on the first contact structure 210. For example, the first mold insulating film 220 may include a nitride-based material, the second mold insulating film 230 may include an oxide-based material, and the third mold insulating film 240 may include a nitride-based material.

Referring to FIG. 18, a part of each of the first mold insulating film 220, the second mold insulating film 230, and the third mold insulating film 240 may be removed to form a first recess RC1 inside the first mold insulating film 220, the second mold insulating film 230, and the third mold insulating film 240. The first recess RC1 may extend in the third direction Z2 inside the first mold insulating film 220, the second mold insulating film 230, and the third mold insulating film 240 to expose the upper side of the first contact structure 210.

After that, a channel region 250 may be formed inside the first recess RC1. The channel region 250 may be formed on the upper side of the third mold insulating film 240, and the side walls and the bottom side of the first recess RC1. The channel region 250 may be in contact with the upper side of the first contact structure 210. The channel region 250 may include the two-dimensional semiconductor material described above. The channel region 250 may be formed by, for example, but not limited to, an atomic layer deposition process (ALD).

Referring to FIG. 19, an insulating pillar 260 that fills the inside of the first recess RC1 may be formed on the channel region 250. The insulating pillar 260 may extend in the third direction Z2 inside the first recess RC1. The insulating pillar 260 may be in contact with the channel region 250. The insulating pillar 260 may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the insulating pillar 260 may include a silicon oxide film. A planarization process may be performed on the upper side of the insulating pillar 260 and the upper side of the channel region 250. Therefore, in some implementations, the upper side of the insulating pillar 260 and the upper side of the channel region 250 may be located on the same plane.

Referring to FIG. 20, the second mold insulating film 230 is removed in the horizontal direction (e.g., the second direction Y2), and a word line WL may be formed in the region in which the second mold insulating film 230 is removed. The word line WL may be interposed between the first mold insulating film 220 and the third mold insulating film 240 in the third direction Z2. The insulating pillar 260 may be interposed between the word lines WL in the second direction Y2. A gate insulating film may be interposed between the word line WL and the channel region 250.

Referring to FIG. 21, a part of the upper part of the insulating pillar 260 may be removed. Thus, the upper side of the insulating pillar 260 may be located below the upper side of the channel region 250. A second contact structure 270 may be formed in the region in which a part of the upper part of the insulating pillar 260 is removed. The second contact structure 270 may be formed on the upper side and a part of the side face of the channel region 250, and upper side of the insulating pillar 260.

The second contact structure 270 may include a fourth contact film 271 and a fifth contact film 272 that are sequentially stacked on the upper side and a part of the side face of the channel region 250, and the upper side of the insulating pillar 260. Each of the fourth contact film 271 and the fifth contact film 272 may include the above-mentioned two-dimensional semiconductor material layer. Although the number of layers of the contact film included in the second contact structure 270 is shown to be two, the number thereof is not limited thereto. The number of layers of the contact film included in the second contact structure 270 may be at least one layer or more. Each of the fourth contact film 271 and the fifth contact film 272 included in the second contact structure 270 may include the same two-dimensional semiconductor material or may include different two-dimensional semiconductor materials from each other. In some implementations, the second contact structure 270 may be referred to as a second contact structure.

After that, referring to FIG. 7, at least a part of the second contact structure 270 on the insulating pillar 260 may be removed. Thus, the second contact structures 270 may be spaced apart from each other on the insulating pillar 260.

After that, an electrode structure CAP may be formed on the second contact structure 270. The second contact structure 270 may be in contact with the storage electrode SE of the electrode structure CAP.

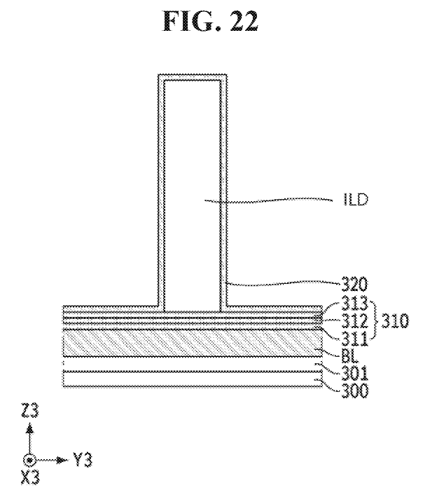

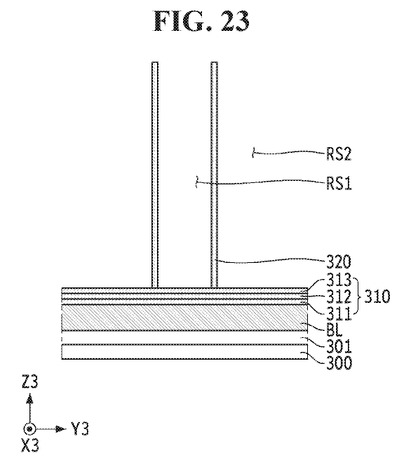

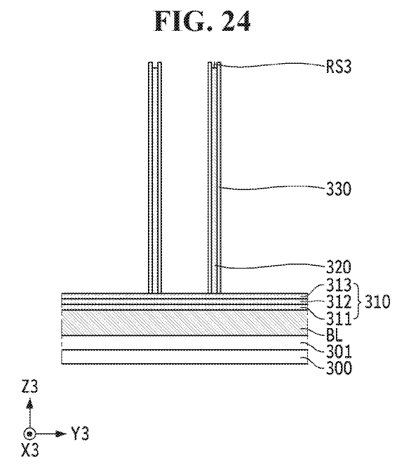

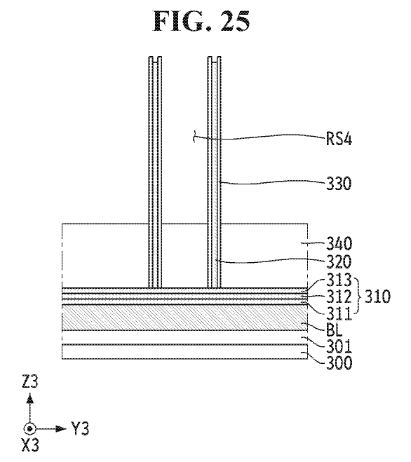

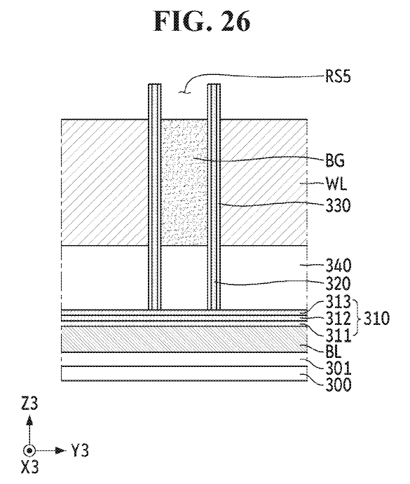

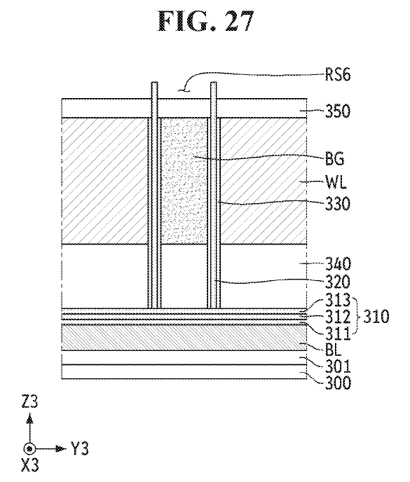

FIGS. 22 - 27 are diagrams illustrating an example of a a method of fabricating a semiconductor memory device, e.g., the semiconductor memory device of FIGS. 8 and 9. For convenience of explanation, repeated parts of contents explained using FIGS. 8 and 9 will be briefly explained or omitted. For reference, FIGS. 22 - 27 are diagrams showing the view of FIG. 9.

Referring to FIG. 22, a lower insulating layer 301 and a bit line BL may be sequentially formed on a third substrate 300. The third substrate 300 may be a silicon substrate or may include other materials, for example, but are not limited to, silicon germanium, indium antimonide, lead telluride, indium arsenide, indium phosphide, gallium arsenide or gallium antimonide. The bit line BL may be disposed on the lower insulating layer 301.

The lower insulating layer 301 may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the lower insulating layer 301 may include a silicon oxide film.

A first contact structure 310 may be formed on the bit line BL. The first contact structure 310 may include a first contact film 311, a second contact film 312, and a third contact film 313 that are sequentially stacked on the bit line BL. Each of the first contact film 311, the second contact film 312, and the third contact film 313 may include the two-dimensional semiconductor material layer described above. Although the number of layers of the contact film included in the first contact structure 310 is shown to be three, the number thereof is not limited thereto. The number of layers of the contact film included in the first contact structure 310 may be at least one layer or more. Each of the first contact film 311, the second contact film 312, and the third contact film 313 included in the first contact structure 310 may include the same two-dimensional semiconductor material or may include different two-dimensional semiconductor materials from each other. In some implementations, the first contact structure 310 may be referred to as a first contact structure.

After that, a mold insulating film may be formed on the first contact structure 310. The mold insulating film may include at least one of, for example, a silicon oxide film, a silicon nitride film, a silicon oxynitride film, a carbon-containing silicon oxide film, a carbon-containing silicon nitride film, and a carbon-containing silicon oxynitride film. As an example, the mold insulating film may include a silicon oxide film.

Thereafter, an etching process may be performed on the mold insulating film to form a mold insulating pattern ILD. The mold insulating pattern ILD may be in contact with a part of an upper side of the first contact structure 310.

Thereafter, a channel region 320 may be formed on the upper side of the first contact structure 310, and the side walls and the upper side of the mold insulating pattern ILD. The channel region 320 may be in contact with the upper side of the first contact structure 310. The channel region 320 may include the two-dimensional semiconductor material described above. The channel region 320 may be formed, for example, but is not limited to, by an atomic layer deposition process (ALD).

Referring to FIG. 23, the mold insulating pattern ILD and the channel region 320 on the mold insulating pattern ILD may be removed to form a first recess RS1 on the first contact structure 310. Channel regions 320 spaced apart in the second direction Y3 may be formed by the first recess RS1. The channel region 320 on the first contact structure 310 may be removed to form a second recess RS2. Each of the first recess RS1 and the second recess RS2 may expose the upper side of the first contact structure 310.

Referring to FIG. 24, gate insulating films 330 may be formed on each side wall of the channel region 320. The gate insulating films 330 may be formed on the channel region 320 in a direction parallel to the third direction Z3.

After that, a part of the upper part of the channel region 320 may be removed to form a third recess RS3. The upper side of the channel region 320 may be recessed and exposed by the third recess RS3. A length of the gate insulating film 330 may be longer than a length of the channel region 320 in the third direction Z3.

Referring to FIG. 25, a first mold insulating film 340 may be formed on the first contact structure 310. For example, the first mold insulating film 340 may include a nitride-based material.

After that, an etching process may be performed on the first mold insulating film 340 to form a fourth recess RS4 that exposes the side wall of the gate insulating film 330. The side wall of the gate insulating film 330 and the upper side of the first mold insulating film 340 may be exposed by the fourth recess RS4.

Referring to FIG. 26, a conductive material may be formed in the fourth recess RS4. The conductive material may be formed on the first mold insulating film 340. Accordingly, word lines WL, and a back gate BG between the word lines WL may be formed. The back gate BG may be formed between the channel regions 320.

After that, the upper parts of the word lines WL and the upper part of the back gate BG may be partially removed to form a fifth recess RS5. The fifth recess RS5 may expose the upper sides of the word lines WL and the upper side of the back gate BG. The fifth recess RS5 may expose the upper parts of the channel regions 320 and the upper parts of the gate insulating films 330. In the third direction Z3, the height of the upper sides of the word lines WL and the upper side of the back gate BG may be lower than the height of the upper sides of the channel regions 320 and the upper sides of the gate insulating films 330.

An etching process may be performed on the upper part of the gate insulating films 330. The upper sides of the channel regions 320 and the upper sides of the gate insulating films 330 may be located on the same plane.

Referring to FIG. 27, the gate insulating films 330 on the word lines WL and the back gate BG may be removed. Therefore, the upper parts of the channel regions 320 may be exposed in the fifth recess RS5 region.

After that, a second mold insulating film 350 may be formed on the word lines WL and the back gate BG. The second mold insulating film 350 may be formed in the fifth recess RS5 region. The second mold insulating film 350 may surround the upper region of the exposed channel region 320. For example, the second mold insulating film 350 may include a nitride-based material.

After that, a part of the upper part of the second mold insulating film 350 may be removed to form a sixth recess RS6. The sixth recess RS6 may expose a part of the side faces and upper side of the channel regions 320 and the upper side of the second mold insulating film 350. Therefore, the channel regions 320 may protrude beyond the second mold insulating film 350 in the third direction Z3.

Next, referring to FIG. 9, a second contact structure 360 that covers the upper parts of the channel regions 320 may be formed on the second mold insulating film 350. Although the number of layers of the contact film included in the second contact structure 360 is shown to be one, the number thereof is not limited thereto. The number of layers of the contact film included in the second contact structure 360 may be at least one layer or more. When the contact films included in the second contact structure 360 are a multilayer structure, each of the contact films may include the same two-dimensional semiconductor material or may include different two-dimensional semiconductor materials from each other. In some implementations, the second contact structure 360 may be referred to as a second contact structure.

After that, an electrode structure CAP may be formed on the second contact structure 360. The second contact structure 360 may be in contact with the storage electrode SE of the electrode structure CAP.

As described above, at least one or more two-dimensional semiconductor material layers may be formed in a first contact structure that is in contact with a bit line BL and a second contact structure that is in contact with a electrode structure CAP. Accordingly, it is possible to improve the resistance characteristics of the contact structure. The two-dimensional semiconductor material layers may form a multilayer structure. The first and second contact structures may include the same two-dimensional semiconductor material layer or may include different two-dimensional semiconductor material layers from each other. The two-dimensional semiconductor material layer may include, but is not limited to, at least one of MoS₂, MoSe₂, WS₂, and WSe₂.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While certain examples have been particularly shown and described, it will be understood that various changes in form and details may be made therein without departing from the spirit and scope of this disclosure.

What is claimed is:

1. A semiconductor memory device comprising:
a substrate;
word lines on the substrate;
a channel region between the word lines;
a first contact structure connected to a first end of the channel region;
a second contact structure connected to a second end of the channel region;
a bit line in contact with the first contact structure; and
an electrode structure in contact with the second contact structure,
wherein the first contact structure includes first two-dimensional semiconductor material layers forming a first multilayer structure, wherein the first two-dimensional semiconductor material layers are between the channel region and the bit line, and
wherein the second contact structure includes second two-dimensional semiconductor material layers forming a second multilayer structure, wherein the second two-dimensional semiconductor material layers are between the channel region and the electrode structure.

2. The semiconductor memory device of claim 1,
wherein the first contact structure is in contact with the first end of the channel region, and
wherein the second contact structure is in contact with the second end of the channel region.

3. The semiconductor memory device of claim 1,
wherein the first contact structure includes a first contact film that is in contact with the first end of the channel region, and a second contact film on the first contact film, the second contact film in contact with the bit line, and
wherein the second contact structure includes a third contact film that is in contact with the second end of the channel region, and a fourth contact film on the third contact film, the fourth contact film in contact with the electrode structure.

4. The semiconductor memory device of claim 1, comprising:
a first spacer pattern extending in a first horizontal direction parallel to an upper side of the substrate, wherein the first spacer pattern is between the bit line and the word lines in a second horizontal direction different from the first horizontal direction;
a second spacer pattern extending in the first horizontal direction, wherein the second spacer pattern is spaced apart from the first spacer pattern in the second horizontal direction; and
an insulating pattern between the word lines in a vertical direction.

5. The semiconductor memory device of claim 1, comprising:
a gate insulating film between the word lines and the channel region,
wherein the word lines, the gate insulating film, and the channel region overlap each other along a vertical direction.

6. The semiconductor memory device of claim 1,
wherein the channel region includes a two-dimensional semiconductor material monolayer.

7. The semiconductor memory device of claim 1,
wherein the first two-dimensional semiconductor material layers of the first contact structure and the second two-dimensional semiconductor material layers of the second contact structure include a same material as each other.

8. The semiconductor memory device of claim 1,
wherein the first contact structure and the second contact structure include different materials from each other.

9. The semiconductor memory device of claim 1,
wherein the first two-dimensional semiconductor material layers of the first contact structure include different materials from each other, and
wherein the second two-dimensional semiconductor material layers of the second contact structure include different materials from each other.

10. The semiconductor memory device of claim 1,
wherein the first contact structure includes at least one of MoS₂ MoSe₂ WS₂ or WSe₂ and
the second contact structure includes at least one of MoS₂ MoSe₂ WS₂ or WSe₂.

11. A semiconductor memory device comprising:
a substrate;
word lines on the substrate in a vertical direction;
a channel region between the word lines, wherein the channel region includes a two-dimensional semiconductor material monolayer;
an insulating pattern between the word lines in the vertical direction;
a first contact structure connected to a first source/drain region of the channel region;
a second contact structure connected to a second source/drain region of the channel region;
a bit line extending in the vertical direction, wherein the bit line is connected to the first contact structure; and
an electrode structure connected to the second contact structure,
wherein the first contact structure is between the channel region and the bit line, wherein the first contact structure includes at least one first two-dimensional semiconductor material layer, and wherein the at least one first two-dimensional semiconductor material layer is in contact with a first upper surface, a first side surface, and a first lower surface of the first source/drain region, and
wherein the second contact structure is between the channel region and the electrode structure, wherein the second contact structure includes at least one second two-dimensional semiconductor material layer, and wherein the at least one second two-dimensional semiconductor material layer is in contact with a second upper surface, a second side surface, and a second lower surface of the second source/drain region.

12. The semiconductor memory device of claim 11, wherein the first side surface of the first source/drain region connects the first upper surface and the first lower surface of the first source/drain region, and
wherein the second side surface of the second source/drain region connects the second upper surface and the second lower surface of the second source/drain region.

13. The semiconductor memory device of claim 11, wherein the first contact structure includes a first contact film that is in contact with the first source/drain region, and a second contact film that is in contact with the bit line, and
wherein the second contact structure includes a third contact film that is in contact with the second source/drain region, and a fourth contact film that is in contact with the electrode structure.

14. The semiconductor memory device of claim 11, comprising:
a first spacer pattern between the bit line and the word lines; and
a second spacer pattern between the electrode structure and the word lines,
wherein the first contact structure is in contact with a side surface of the first spacer pattern, and
wherein the second contact structure is in contact with a side surface of the second spacer pattern.

15. The semiconductor memory device of claim 11,
wherein the electrode structure includes a plate electrode, and a capacitor dielectric film between the plate electrode and the second contact structure, and
wherein the second contact structure is in contact with the capacitor dielectric film.

16. A semiconductor memory device comprising:
a substrate;
word lines extending on the substrate in a first horizontal direction parallel to an upper side of the substrate, wherein the word lines are spaced apart from each other in a second horizontal direction different from the first horizontal direction;
a channel region between the word lines in the second horizontal direction, wherein the channel region includes a two-dimensional semiconductor material monolayer;
a first contact structure connected to a first region of the channel region;
a second contact structure connected to a second region of the channel region;
a bit line which extends in the second horizontal direction on the substrate, and is connected to the first contact structure; and
an electrode structure which is connected to the second contact structure,
wherein the first contact structure is between the first region and the bit line, wherein the first contact structure includes first two-dimensional semiconductor material layers forming a first multilayer structure, and wherein the first multilayer structure is in contact with the first region, and
wherein the second contact structure is between the second region and the electrode structure, wherein the second contact structure includes second two-dimensional semiconductor material layers forming a second multilayer structure, and wherein the second multilayer structure is in contact with the second region.

17. The semiconductor memory device of claim 16, comprising:
a first insulating pattern between the word lines in the second horizontal direction; and
a second insulating pattern on the word lines in a vertical direction.

18. The semiconductor memory device of claim 17,
wherein the first two-dimensional semiconductor material layers each extend in the second horizontal direction on the bit line, and
wherein the second two-dimensional semiconductor material layers each extend along an upper side and a side wall of the second insulating pattern on the second region.

19. The semiconductor memory device of claim 16, comprising:
a back gate between the word lines in the second horizontal direction, wherein the back gate includes a conductive material.

20. The semiconductor memory device of claim 19,
wherein the first two-dimensional semiconductor material layers each extend in the second horizontal direction on the bit line, and
wherein the second two-dimensional semiconductor material layers each extend along a surface of the second region.
